(19) United States
(12) Patent Application Publication
(10) Pub. No.: US 2026/0006851 A1
(43) Pub. Date: Jan. 1, 2026

(54) INTEGRATED CIRCUIT DEVICE INCLUDING A PERIPHERAL CIRCUIT AND METHOD OF MANUFACTURING THE SAME

(71) Applicant: SAMSUNG ELECTRONICS CO., LTD., SUWON-SI (KR)

(72) Inventors: Hongwoo Seo, Suwon-si (KR); Hoil Bang, Suwon-si (KR); Junseong Song, Suwon-si (KR); Gyuhyun Kil, Suwon-si (KR); Hyunwoo Kim, Suwon-si (KR); Hwarang Kim, Suwon-si (KR)

(21) Appl. No.: 19/022,366

(22) Filed: Jan. 15, 2025

(30) Foreign Application Priority Data
Jun. 26, 2024 (KR) 10-2024-0083586

(51) Int. Cl. H10D 30/67; H10B 12/00; H10D 64/66

(52) U.S. Cl. CPC H10D 30/6757; H10B 12/50; H10D 30/6733; H10D 30/6755; H10D 64/665; H10D 64/667

(57) ABSTRACT

An integrated circuit device including a plurality of gate stacks disposed on a substrate and including a first gate stack and a second gate stack, a spacer disposed on sidewalls of each of the plurality of gate stacks, a plurality of source/drain areas disposed in an upper portion of the substrate and at sides of the plurality of gate stacks, an active area disposed in the upper portion of the substrate and between adjacent source/drain areas of the plurality of source/drain areas, a channel semiconductor layer disposed between the active area and the second gate stack among the plurality of gate stacks.

### CROSS-REFERENCE TO RELATED APPLICATION

This application is based on and claims priority under 35 USC § 119 to Korean Patent Application No. 10-2024-0083586, filed on Jun. 26, 2024, in the Korean Intellectual Property Office, the disclosure of which is incorporated by reference herein in its entirety.

### BACKGROUND

### 1. Technical Field

The inventive concept relates to an integrated circuit device and a manufacturing method thereof, and more particularly, to an integrated circuit device including a peripheral circuit and a manufacturing method thereof.

### 2. Discussion of Related Art

A semiconductor device may include a plurality of transistors. The transistors of the semiconductor device may have various structures. For example, the transistors may be structured as an NMOS transistor or a PMOS transistor, which may have different stacked structures. An isolation structure may be formed in a substrate between the transistors.

### SUMMARY

The inventive concept provides an integrated circuit device with improved reliability and a manufacturing method thereof.

According to an aspect of the inventive concept, there is provided an integrated circuit device including a plurality of gate stacks disposed on a substrate and including a first gate stack and a second gate stack, a spacer disposed on sidewalls of each of the plurality of gate stacks, a plurality of source/drain areas disposed in an upper portion of the substrate and at sides of the plurality of gate stacks, an active area disposed in the upper portion of the substrate and between adjacent source/drain areas of the plurality of source/drain areas, and a channel semiconductor layer disposed between the active area and the second gate stack among the plurality of gate stacks, wherein an upper level of a first portion of the active area is disposed at a lower portion of the second gate stack is higher than an upper level of a second portion of the active area disposed at a lower portion of the second gate stack.

According to another aspect of the inventive concept, there is provided an integrated circuit device including a plurality of gate stacks disposed on a substrate and including a gate electrode and a gate capping layer, the plurality of gate stacks including a first gate stack, a second gate stack, a third gate stack, and a fourth gate stack, a spacer disposed on sidewalls of each of the plurality of gate stacks, the spacer including an inner spacer disposed on the sidewalls of each of the plurality of gate stacks and an outer spacer disposed on the inner spacer on the sidewalls of each of the plurality of gate stacks, a plurality of source/drain areas disposed at sides of each of the plurality of gate stacks in an upper portion of the substrate, an active area disposed in the upper portion of the substrate and between the plurality of source/drain areas, a channel semiconductor layer disposed between the active area and the third gate stack among the plurality of gate stacks, a protective layer covering each of the spacer and the plurality of gate stack, and an interlayer insulating film disposed on an upper surface of the protective layer, wherein the active area is configured such that an upper level of the active area varies, the upper level of a portion of the active area disposed at a lower portion of the third gate stack is lower than the upper level of another portion of the active area, and the channel semiconductor layer is conformally formed on an upper surface of the active area.

According to another aspect of the inventive concept, there is provided an integrated circuit device including an element isolation film disposed on a substrate and defining an active area, a plurality of gate stacks disposed on the active area of the substrate and including a gate electrode and a gate capping layer, and the plurality of gate stacks including a first gate stack, a second gate stack, a third gate stack, and a fourth gate stack, a spacer disposed on sidewalls of each of the plurality of gate stacks and including an inner spacer and an outer spacer, a plurality of source/drain areas disposed at sides of the plurality of gate stacks and in an upper portion of the substrate, and a channel semiconductor layer disposed between the active area and the third gate stack among the plurality of gate stacks, wherein an upper level of a portion of the active area disposed at a lower portion of the third gate stack is lower than the upper levels of portions of the active area disposed at lower portions of the first gate stack, the second gate stack, and the fourth gate stack, the channel semiconductor layer is conformally formed on an upper surface of the active area at the lower portion of the third gate stack, the active area at the lower portion of the third gate stack has an upper surface with a conformal level, the uppermost levels of the first gate stack to the fourth gate stack are different from each other, the uppermost level of the third gate stack is lower than or equal to the uppermost level of the fourth gate stack, the uppermost level of the first gate stack is lower than or equal to the uppermost levels of the remaining gate stacks, wherein the first gate stack is disposed directly on the active area, and wherein each of the second gate stack and the fourth gate stack comprises a gate insulating layer disposed on the active area.

### BRIEF DESCRIPTION OF THE DRAWINGS

Embodiments will be more clearly understood from the following detailed description taken in conjunction with the accompanying drawings in which:

FIG. 1A is a cross-sectional view illustrating a gate stack portion of an integrated circuit device according to a comparative embodiment;

FIG. 1B is a cross-sectional view illustrating a gate stack portion of an integrated circuit device according to an embodiment;

FIG. 2A is a cross-sectional view illustrating an active area portion of an integrated circuit device according to a comparative embodiment;

FIG. 2B is a cross-sectional view illustrating an active area portion of an integrated circuit device according to an embodiment;

FIG. 3 is a layout diagram illustrating an integrated circuit device according to an embodiment;

FIG. 4 is an enlarged layout diagram of portion II of FIG. 3;

FIG. 5 is a cross-sectional view taken along line A-A′ of FIG. 4;

FIGS. 6 to 10 are cross-sectional views illustrating a method of manufacturing an integrated circuit device, according to an embodiment;

FIG. 11 is an enlarged view illustrating a shape of an active area of an integrated circuit device before and after processing according to an embodiment;

FIG. 12 is a transmission electron microscope image of an active area of an integrated circuit device under different process conditions according to an embodiment;

FIG. 13 is a cross-sectional view of an active area of an integrated circuit device under different process conditions according to an embodiment;

FIG. 14 is a graph comparing results of different conditions for an integrated circuit device according to an embodiment;

FIG. 15 is a graph comparing an etching amount by an etching process for an integrated circuit device according to an embodiment;

FIG. 16 is a graph comparing an etching amount by another etching process for an integrated circuit device according to an embodiment;

FIG. 17 is a block diagram of an electronic device according to an embodiment; and

FIG. 18 is a block diagram of an electronic system according to an embodiment.

### DETAILED DESCRIPTION

Hereinafter, embodiments will be described with reference to the accompanying drawings. In the drawing, like reference characters denote like elements, and redundant descriptions thereof may be omitted.

Embodiments described herein are merely exemplary. Embodiments may have various modifications and may take various forms, and some embodiments are illustrated in the drawings and described in detail. However, this is not intended to limit embodiments to a particular modes of practice, and it is to be appreciated that all changes, equivalents, and substitutes that do not depart from the spirit and technical scope of the inventive concept are encompassed in the disclosure.

Any use of examples or exemplary terms is intended merely to elaborate technical ideas and is not intended to limit the scope unless otherwise defined by the claims.

Unless otherwise specified, in this specification, a vertical direction is defined as a Z direction, and a first horizontal direction and a second horizontal direction may each be defined as horizontal directions perpendicular to the Z direction. The first horizontal direction may be referred to as X, and the second horizontal direction may be referred to as Y. A vertical level may refer to a height level along the vertical direction Z. The first horizontal direction and a horizontal width may refer to a length in the horizontal direction X and/or Y, and a vertical length may refer to a length in the vertical direction Z.

Directional phrases and terms may be used for understanding of the disclosure. For example, a top surface may be an upper surface in an illustration. However, this is not intended to limit embodiments. For example, the layer may be turned over, and a top surface thereof may become a bottom surface.

It will be understood that although the terms such as ‘first’ and ‘second’ are used herein to describe various elements, these elements should not be limited by these terms. The terms are only used to distinguish components from each other. For example, a first element referred to as a first element can be referred to as a second element elsewhere without departing from the scope of the appended claims.

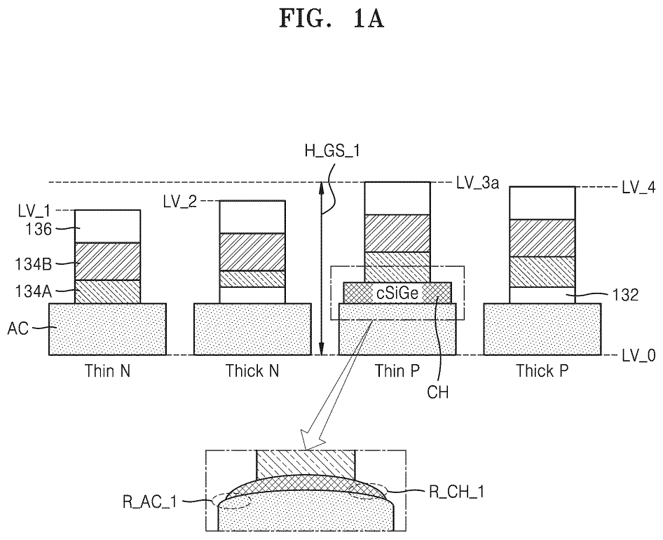

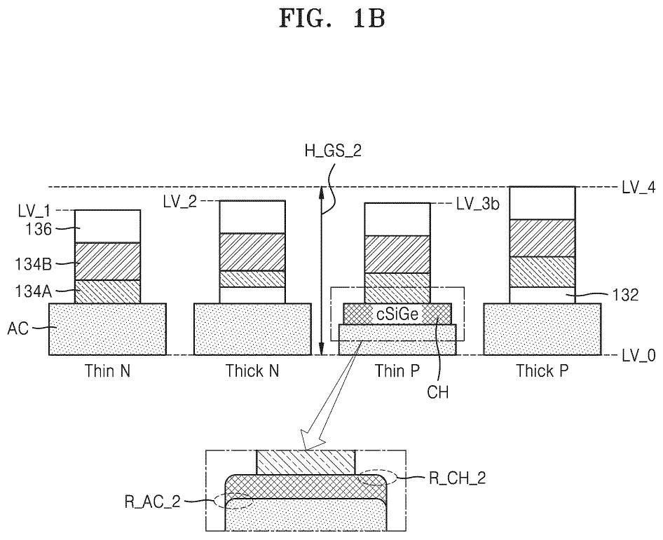

FIG. 1A is a cross-sectional view illustrating a gate stack portion of an integrated circuit device according to a comparative embodiment. FIG. 1B is a cross-sectional view illustrating a gate stack portion of an integrated circuit device according to an embodiment.

The integrated circuit device of the inventive concept may include at least two or more gate stacks. Although four gate stacks are illustrated in FIG. 1B, the number of gate stacks is not necessarily limited to that of the drawings. The gate stacks may be disposed on an upper surface of an active area AC. The gate stacks, from left to right, include a thin n-channel metal-oxide semiconductor (NMOS), a thick NMOS, a thin p-channel metal-oxide semiconductor (PMOS), and a thick PMOS. The term “Thin N” corresponds to Thin NMOS, “Thin P” corresponds to Thin PMOS, “Thick N” corresponds to Thick NMOS, and “Thick P” corresponds to Thin PMOS in the figure.

The gate stack may include a plurality of gate electrodes and a gate capping layer 136. Some of the gate stacks may include a gate insulating layer 132. In an embodiment, the thick NMOS and the thick PMOS may include the gate insulating layer 132. The gate electrode may include a plurality of gate electrodes. In an embodiment, the gate electrode may include a first gate electrode 134A and a second gate electrode 134B. However, the number of gate electrodes is not necessarily limited thereto. The second gate electrode 134B may be disposed on an upper surface of the first gate electrode 134A. The gate capping layer 136 may be disposed on an upper surface of the second gate electrode 134B. The gate insulating layer 132 may be disposed on a lower surface of the first gate electrode 134A.

The first gate electrode 134A, the second gate electrode 134B, the gate capping layer 136, and the gate insulating layer 132 may have the same or different thicknesses from each other, and the thickness of each component illustrated in the drawing is not necessarily limited thereto.

The integrated circuit device of the inventive concept may include a channel semiconductor layer CH. The channel semiconductor layer CH may be disposed in the thin PMOS. A channel semiconductor layer CH may be omitted from the thin NMOS and the thick PMOS. The channel semiconductor layer CH may be disposed beneath the first gate electrode 134A of the thin PMOS. The channel semiconductor layer CH may include silicon germanium (SiGe) and may be referred to as cSiGe.

The channel semiconductor layer CH may be grown on the active area AC. A process for growing the channel semiconductor layer CH may be an epitaxial growth process. Referring to FIG. 1A, a height difference between the thin PMOS and the thin NMOS may be increased due to the grown channel semiconductor layer CH of the thin PMOS. The inventive concept provides a method of reducing an instability of the device structure that may be caused by a dent structure resulting from a height difference between the thin PMOS and the thin NMOS.

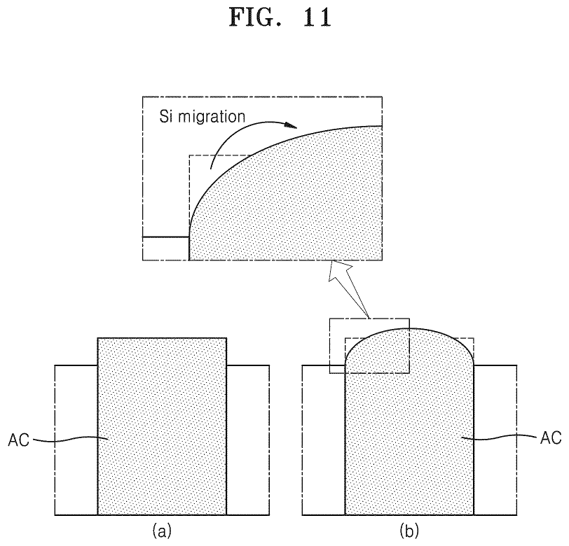

Description will now turn to a thin PMOS structure. In the thin PMOS, a bake process using hydrogen (H₂) gas may be performed on the active area AC before the channel semiconductor layer CH is formed. Referring to the enlarged view shown together in FIG. 1A; when a bake process is performed, a rounding phenomenon may occur in which a vertical level of the active area AC in the thin PMOS decreases at both sides (i.e., the edge areas) and increases at the central area. Details of the rounding phenomenon are explained with reference to FIG. 11. Due to the rounding phenomenon, the channel semiconductor layer CH grown on the active area AC may be formed with a rounded shape. The rounding phenomenon may cause a curvature R_AC_1 of the active area AC and a curvature R_CH_1 of the channel semiconductor layer CH.

Due to the rounding phenomenon, a height LV_3a of the thin PMOS may be increased. In regard to a height of each gate stack shown in FIG. 1A, it may be seen that the height LV_3a of the thin PMOS may be formed to have a relatively high level. A height LV_4 of the thick PMOS may be less than the height LV_3a. A height LV_2 of the thick NMOS may be less than the height LV_4. A height LV_1 of the thin NMOS may be less than the height LV_2. The height LV_2 may be a relatively low level. The height of the gate stack may be defined as H_GS_1, ranging from a reference vertical level LV_0 to the height LV_3a, which may be a height to an uppermost end of the thin PMOS.

In exemplary embodiments, a profile of a semiconductor device above a plurality of gate stacks of an integrated circuit device, which may have various heights, may be flattened. This may be accomplished by forming an active area having various heights, and disposing a channel semiconductor layer of a relatively tall gate stack at least partially in the substrate on a low portion of the active area, reducing an overall height of the gate stack and reducing a variation between the heights of the plurality of gate stacks. FIG. 1B shows an integrated circuit device of the inventive concept, in which a separate process may be performed to etch the active area AC of the thin PMOS, which may lower the vertical level of the active area AC of the thin PMOS and conformally forming the active area AC. Since the active area AC is formed conformally, the channel semiconductor layer CH grown on the active area AC may also be formed conformally. Here, “conformal” means that the vertical levels of the upper surface may be nearly uniform, indicating that it is flattened. This may inhibit or prevent the rounding phenomenon. As a result, the curvature R_AC_2 of the active area AC may be reduced and the curvature R_CH_2 of the channel semiconductor layer CH may be reduced compared to those of FIG. 1A.

As a result, the height LV_3b of the thin PMOS may be reduced. Referring to the height of each gate stack shown in FIG. 1B, it is confirmed that the height LV_4 of the thick PMOS may be formed to have a relatively high level. The height LV_2 of the thick NMOS may be less than the height LV_4. The height LV_3b of the thin PMOS may be less than the height LV_2. The height LV_1 of the thin NMOS may be less than the height LV_1. However, the order of the height LV_3b of the thin PMOS, the height LV_2 of the thick NMOS, and the height LV_1 of the thin NMOS may differ from those illustrated in the drawings. For example, the height LV_2 of the thick NMOS and the height LV_3b of the thin PMOS may be the same height. The height of the gate stack may be defined as H_GS_2, ranging from the reference vertical level LV_0 to the height LV_4, which is a height to an uppermost end of the thick PMOS. Therefore, the H_GS_2 may be lower than H_GS_1. In other words, the height of the gate stack may ultimately be reduced.

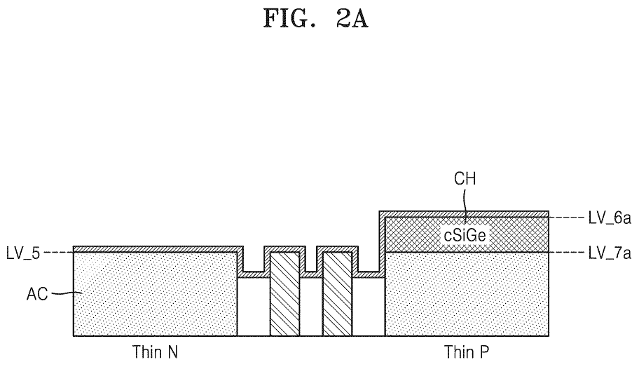

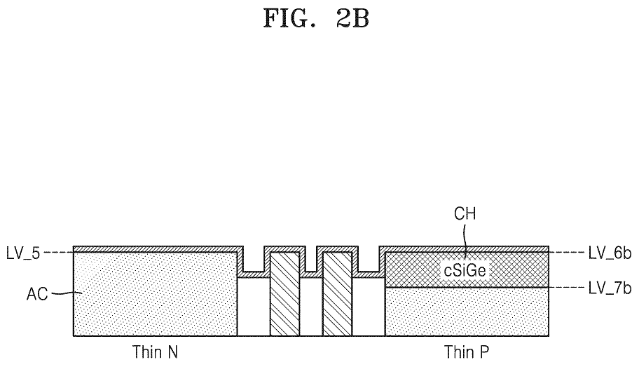

FIG. 2A is a cross-sectional view showing an active area portion of an integrated circuit device according to a comparative embodiment. FIG. 2B is a cross-sectional view showing an active area portion of an integrated circuit device according to an embodiment.

FIG. 2A illustrates the appearance before the gate stack is formed as depicted in FIG. 1A. According to a comparative embodiment, a vertical level LV_5 of the active area AC of the thin NMOS may be less than or equal to a vertical level LV_7a of the active area AC of the thin PMOS. If LV_5 is lower than LV_7a, this may have been caused by the rounding phenomenon described above. As a result, a vertical level LV_6a of the channel semiconductor layer CH grown on the active area AC of the thin PMOS may be formed higher than the vertical level LV_5 of the active area AC of the thin NMOS. As a result, a height difference or a dent structure may occur. In FIG. 2A, the rounded shapes of the active area AC and the channel semiconductor layer CH are not depicted but are simply represented; however, if enlarged as in FIG. 1A, the active area AC and the channel semiconductor layer CH may be formed in a rounded shape. The rounded shape may cause tilting of the gate stack. This may cause a threshold voltage Vt shift or defects in a profile of the gate stack.

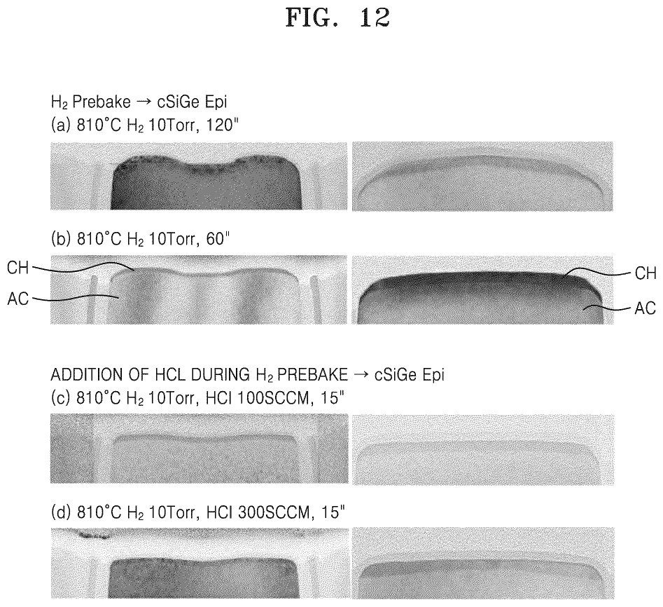

FIG. 2B shows that, by performing an etching process on the active area AC of the thin PMOS as described in FIG. 1B, the rounding phenomenon may be suppressed, and the active area AC may be formed relatively conformally. By a manufacturing process of the inventive concept, a vertical level LV_7b of the active area AC of the thin PMOS may be lower than the LV_7a according to a comparative embodiment, and LV_7b may be lower than the vertical level LV_5 of the active area AC of the thin NMOS. As a result, a vertical level LV_6b of the channel semiconductor layer CH may be lower than LV_6a depicted in FIG. 2A. LV_6b may be lower than or equal to LV_5. Detailed information on etching the active area AC of the thin PMOS will be described in connection with FIG. 12.

In an example in which the active area AC may be formed to have a conformally formed upper surface, a protrusion extending upward may be inhibited or prevented. A gate stack formed on the active area formed having a conformally formed upper surface may have a relatively low level.

Through this, a structure with an improved height difference between NMOS and PMOS may be formed, and an improved structure may reduce the vertical metal thickness and may suppress an over etch. Furthermore, by mitigating a dent structure, a residue-free interface may be obtained, which may contribute to improving gate reliability.

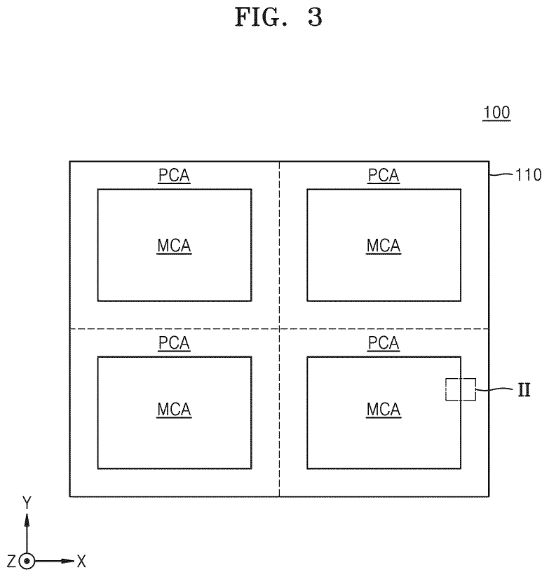

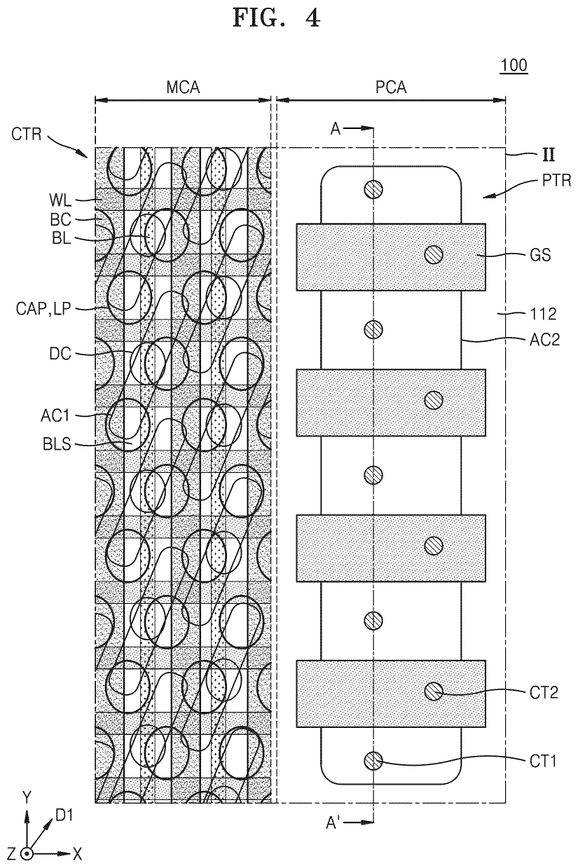

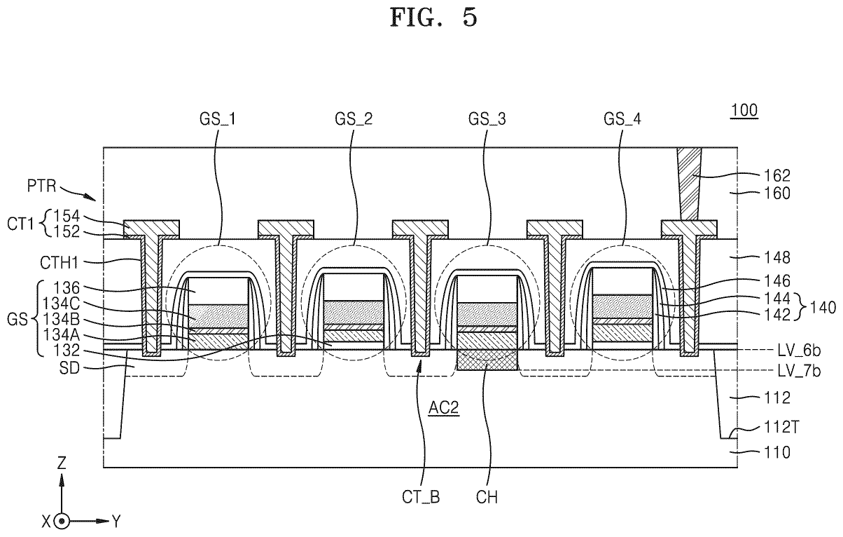

FIG. 3 is a layout diagram showing an integrated circuit device according to an embodiment. FIG. 4 is an enlarged layout diagram of portion II of FIG. 3. FIG. 5 is a cross-sectional view taken along line A-A′ of FIG. 4.

Referring to FIGS. 3 to 5, an integrated circuit device 100 may include a substrate 110 including a cell array area MCA and a peripheral circuit area PCA. The cell array area MCA may be a memory cell area of a dynamic random-access memory (DRAM) device, and the peripheral circuit area PCA may be a core area or a peripheral circuit area of the DRAM device. For example, the cell array area MCA may include a cell transistor CTR and a cell capacitor CAP, and the peripheral circuit area PCA may include a peripheral circuit transistor PTR for transmitting signals and/or power to the cell transistor CTR included in the cell array area MCA. In some embodiments, the peripheral circuit transistor PTR may form various circuits including a command decoder, control logic, address buffer, row decoder, column decoder, sense amplifier, or data input/output circuit.

An element isolation trench 112T may be formed in the substrate 110 and an element isolation film 112 may be formed within the element isolation trench 112T. By the element isolation film 112, a plurality of first active areas AC1 may be defined on the substrate 110 in the cell array area MCA, and a plurality of second active areas AC2 may be defined on the substrate 110 in the peripheral circuit area PCA. The second active area AC2 may correspond to the active area AC described with reference to FIG. 1B and FIG. 2B.

In the cell array area MCA, the plurality of first active areas AC1 may be disposed to have their long axis in a diagonal direction D1 inclined with respect to a first horizontal direction X and a second horizontal direction Y, respectively. A plurality of word lines WL may extend in parallel with each other along the first horizontal direction X across the plurality of first active areas AC1. In some embodiments, the cell transistor CTR may have a buried channel array transistor (BCAT) structure, and for example, a plurality of word lines WL may be disposed within a word line trench extending in the first horizontal direction X within the substrate 110.

A plurality of bit lines BL may extend in parallel with each other along the second horizontal direction Y and above the plurality of word lines WL. The plurality of bit lines BL may be connected to the plurality of the first active areas AC1 via a direct contact DC. A bit line spacer BLS may be disposed on sidewalls of each of the plurality of bit lines BL. A plurality of buried contacts BC may be formed between adjacent bit lines BL among the plurality of bit lines BL. The plurality of buried contacts BC may be arranged in a row along the first horizontal direction X and the second horizontal direction Y.

A plurality of landing pads LP may be formed above the plurality of buried contacts BC. A cell capacitor CAP may be disposed in a position vertically overlapping with the plurality of landing pads LP. For example, the cell capacitor CAP may include a metal-insulator-metal (MIM) capacitor including a lower electrode, an upper electrode, and a capacitor dielectric layer interposed therebetween.

The substrate 110 may include silicon, including single crystal silicon, polycrystalline silicon, or amorphous silicon. In an embodiment, the substrate 110 may include at least one of Ge, SiGe, SiC, GaAs, InAs, or InP. In some embodiments, the substrate 110 may include a conductive area, for example, a well doped with impurities or a structure doped with impurities. The element isolation film 112 may include an oxide film, a nitride film, or a combination thereof.

In the peripheral circuit area PCA, a peripheral circuit transistor PTR may be disposed on the second active area AC2. The peripheral circuit transistor PTR may include a gate stack GS disposed on the second active area AC2, and a source/drain area SD disposed at sides of the gate stack GS.

The source/drain area SD may be disposed at sides of the gate stack GS in an upper portion of the second active area AC2. The source/drain area SD may be an area of the substrate 110 that may be doped with impurities, and may include, for example, silicon doped with impurities. In some embodiments, the impurities doped into the source/drain area SD may include boron (B).

The gate stack GS may include the first gate electrode 134A, the second gate electrode 134B, the third gate electrode 134C, and the gate capping layer 136. A second gate stack and a fourth gate stack among the gate stacks GS may include the gate insulating layer 132. The gate insulating layer 132 may include at least one selected from a silicon oxide film, a silicon nitride film, a silicon oxynitride film, an oxide/nitride/oxide (ONO) film, or a high-k dielectric film having a dielectric constant higher than that of a silicon oxide film. The gate capping layer 136 may include a silicon nitride film. From a lower surface to an upper surface of the gate stack GS, the first gate electrode 134A, the second gate electrode 134B, and the third gate electrode 134C may be disposed sequentially. Vertical thicknesses of each of the first gate electrode 134A, the second gate electrode 134B, and the third gate electrode 134C may be different from each other. The gate stack GS may include a first gate stack GS_1, a second gate stack GS_2, a third gate stack GS_3, and a fourth gate stack GS_4. Each of the first gate stack GS_1 and the second gate stack GS_2 may form an NMOS. Each of the third gate stack GS_3 and the fourth gate stack GS_4 may form a PMOS. The first gate stack GS_1 may correspond to the thin NMOS described with reference to FIG. 1B. The second gate stack GS_2 may correspond to the thick NMOS described with reference to FIG. 1B. The third gate stack GS_3 may correspond to the thin PMOS described with reference to FIG. 1B. The fourth gate stack GS_4 may correspond to the thick PMOS described with reference to FIG. 1B.

An uppermost level of each of the first gate stack GS_1, the second gate stack GS_2, the third gate stack GS_3, and the fourth gate stack GS_4 may be different from each other. The uppermost level of the third gate stack GS_3 may be lower than or equal to the uppermost level of the fourth gate stack GS_4. The uppermost level of the first gate stack GS_1 may be lower than or equal to the uppermost levels of the remaining gate stacks.

In embodiments, the first gate electrode 134A may include at least one of Si, Ge, W, WN, Co, Ni, Al, Mo, Ru, Ti, TiN, Ta, TaN, Cu, or La, or a combination thereof. The second gate electrode 134B and the third gate electrode 134C may include at least one of TiN, TiSiN, W, or tungsten silicide, or a combination thereof.

In embodiments, the materials of each of the first gate electrode 134A, the second gate electrode 134B, and the third gate electrode 134C may be identical to the materials of the bit line BL in the cell array area MCA. For example, the first gate electrode 134A, the second gate electrode 134B, and the third gate electrode 134C may be formed simultaneously in a process of forming the bit line BL. However, the inventive concept is not necessarily limited thereto.

Sidewalls of the gate stack GS may be covered with a spacer 140. The spacer 140 may include an inner spacer 142 and an outer spacer 144. For example, the inner spacer 142 may be disposed directly on sidewalls of the gate stack GS and may include a first insulating material. The outer spacer 144 may be disposed on the inner spacer 142 on sidewalls of the gate stack GS, and may include a second insulating material different from the first insulating material. The inner spacer 142 may be disposed between the outer spacer 144 and the gate stack GS, and the outer spacer 144 may not directly contact the sidewalls of the gate stack GS. For example, the outer spacer 144 may be spaced apart from the sidewalls of the gate stack GS. In embodiments, the first insulating material may include silicon nitride and the second insulating material may include silicon oxide.

The integrated circuit device 100 may include a channel semiconductor layer CH. The channel semiconductor layer CH may be disposed between the second active area AC2 and the third gate stack GS_3 among the plurality of gate stacks GS. The second active area AC2 may be configured such that an upper level thereof may vary. Among the second active areas AC2, the upper level LV_7b of the active area AC located at a lower portion of the third gate stack GS_3 may be formed to be a low level.

Referring to FIG. 5, the upper level LV_7b of the active area AC located at a lower portion of the third gate stack GS_3 may be formed to be higher than a bottom of the source/drain areas SD disposed at sides of the third gate stack GS_3. However, the inventive concept is not necessarily limited thereto. For examples, the upper level LV_7b of the active area AC located at a lower portion of the third gate stack GS_3 may be formed to be at a same level as the bottom of the source/drain areas SD disposed at sides of the third gate stack GS_3.

The channel semiconductor layer CH may be conformally formed on an upper surface of a portion of the second active area AC2, which has a low upper level. The upper level LV_6b of the channel semiconductor layer CH may be formed to be equal to or lower than an uppermost level of the second active area AC2. The second active area AC2 having the low upper level may have an upper surface with a conformal level.

The channel semiconductor layer CH may include silicon germanium (SiGe). Here, the inclusion of silicon germanium (SiGe) in the channel semiconductor layer CH means that the elements forming the channel semiconductor layer CH include silicon and germanium. The relevant content of silicon and germanium in the channel semiconductor layer CH may vary. The channel semiconductor layer CH may be formed by performing an epitaxial growth process on the second active area AC2. A bake process and an etching process of the second active area AC2 may be conducted simultaneously, and the channel semiconductor layer CH may be formed in an etched portion. A process of forming the active area AC having the low upper level, where the channel semiconductor layer CH grows, may differ from a process performed on other active areas and may be performed independently.

The channel semiconductor layer CH may be configured to have a thickness corresponding to a difference between the uppermost level of the second active area AC2 and the vertical level LV_6b of the second active area AC2 having the lowest upper level. An upper surface of the section active area AC2 and the substrate 110 may be coplanar. However, the inventive concept is not limited thereto. For example, the channel semiconductor layer CH may be configured to have a height above the substrate 110. A height of the channel semiconductor layer CH above a height above the substrate 110 may be configured such that a height of the third gate stack GS_3 may be about equal to a tallest gate stack among the first gate stack GS_1, the second gate stack GS_2, and the fourth gate stack GS_4. For example, a height of the third gate stack GS_3 may be about equal to a height of the fourth gate stack GS_4 based on a height of the channel semiconductor layer CH above a height above the substrate 110. In this case, the channel semiconductor layer CH may at least partially overlap in a horizontal direction with the spacer 140.

The gate stack GS and the spacer 140 may be covered with a protective layer 146, and a first interlayer insulating film 148 may be disposed on the protective layer 146. The first interlayer insulating film 148 may cover the sidewalls of the gate stack GS and the spacer 140.

In exemplary embodiments, the bottom surface of the inner spacer 142 and the bottom surface of the outer spacer 144 may be disposed on the top surface of the substrate 110.

A contact CT1 may be disposed within a contact hole CTH1 penetrating the first interlayer insulating film 148 and the protective layer 146 in the peripheral circuit area PCA. The contact CT1 may include a conductive barrier 152 and a contact conductive layer 154. The contact CT1 may contact the substrate 110. In embodiments, the conductive barrier 152 may include at least one of ruthenium (Ru), titanium (Ti), titanium nitride (TiN), tantalum (Ta), tantalum nitride (TaN), tungsten (W), titanium silicon nitride (TiSiN), titanium silicide (TiSi), or tungsten silicide (WSi). The contact conductive layer 154 may include at least one of tungsten (W), cobalt (Co), molybdenum (Mo), nickel (Ni), ruthenium (Ru), copper (Cu), aluminum (Al), or a silicide thereof, or an alloy thereof.

A bottom portion CT_B of the contact CT1 may be in contact with the source/drain area SD of the substrate 110, and a bottom surface of the contact CT1 may be disposed at a level lower than an upper surface of the source/drain area SD.

As shown in FIG. 4, a gate contact CT2 may be disposed to be connected to the gate stack GS. For example, the gate contact CT2 may penetrate the protective layer 146, the first interlayer insulating film 148, and the gate capping layer 136 to be electrically connected to an upper surface of the third gate electrode 134C. A second interlayer insulating film 160 may be disposed on the first interlayer insulating film 148, and an upper contact 162 may be disposed to penetrate the second interlayer insulating film 160 and be connected to the contact CT1. Upper portions of the contacts CT1 may be electrically isolated by the second interlayer insulating film 160.

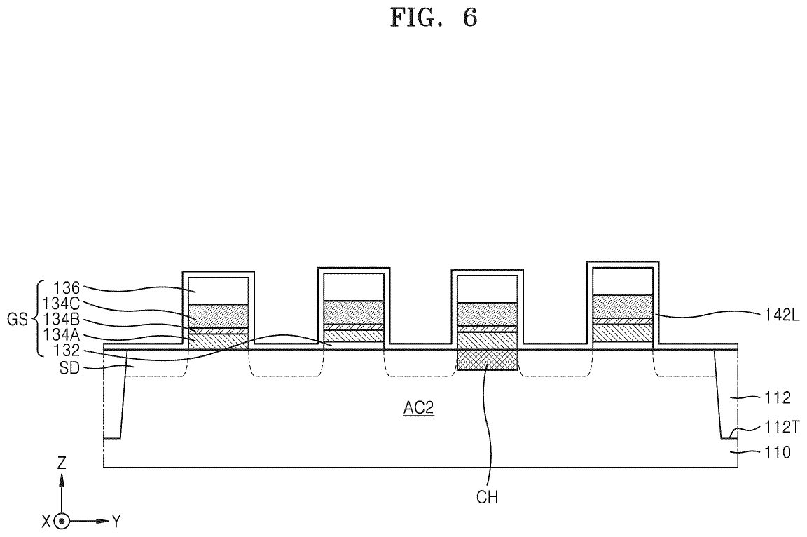

FIGS. 6 to 10 are cross-sectional views showing a method of manufacturing an integrated circuit device, according to an embodiment.

Referring to FIG. 6, together with FIGS. 1B, 2B, and 3 to 5, a plurality of element isolation trenches 112T may be formed in the cell array area MCA and the peripheral circuit area PCA of the substrate 110, and the element isolation film 112 may be formed in the plurality of element isolation trenches 112T in the cell array area MCA and the peripheral circuit area PCA. By forming the element isolation film 112, the plurality of first active areas AC1 may be defined in the cell array area MCA of the substrate 110, and the second active area AC2 may be defined in the peripheral circuit area PCA. In some embodiments, the element isolation film 112 may be formed using silicon oxide, silicon nitride, or silicon oxynitride, or a combination thereof. In some examples, the element isolation film 112 may be formed as a double layer structure of a silicon oxide layer and a silicon nitride layer, but is not necessarily limited thereto.

In the cell array area MCA, a portion of the substrate 110 may be removed to form a word line trench, and a word line WL may be formed within the word line trench.

A bake process and an etching process may be performed simultaneously on the active area AC where the third gate stack GS_3 will be disposed. In an etching process, hydrogen gas may be used. In an etching process hydrogen gas and hydrogen chloride gas may be used. Detailed information on an example bake and etch processes will be explained after FIG. 12. In regard to the etched active area AC, as described herein, the channel semiconductor layer CH may include silicon germanium and may be formed by an epitaxial growth process. The epitaxial growth process may be a chemical vapor deposition (CVD) process including vapor-phase epitaxy (VPE), ultra-high vacuum chemical vapor deposition (UHV-CVD), or molecular beam epitaxy, or a combination thereof. In an epitaxial growth process, a liquid or gaseous precursor may be used as a precursor for forming the channel semiconductor layer CH.

Afterwards, in the peripheral circuit area PCA, the gate insulating layer 132 may be formed on the substrate 110. However, the gate insulating layer 132 may be removed from the upper surface of the active area AC on which the first gate stack and the third gate stack may be disposed. In some embodiments, the gate insulating layer 132 may be formed on an exposed surface of the second active area AC2. The gate insulating layer 132 may not be formed on the element isolation film 112. In an embodiment, the gate insulating layer 132 may be formed on the exposed surface of the second active area AC2 and an upper surface of the element isolation film 112.

The bit line BL and a gate stack GS may be formed on the substrate 110 in the cell array area MCA and the peripheral circuit area PCA, respectively.

In some embodiments, the gate stack GS may include the gate insulating layer 132, the first gate electrode 134A, the second gate electrode 134B, the third gate electrode 134C, and the gate capping layer 136 sequentially arranged on the second active area AC2. However, the gate insulating layer 132 may be included in the second gate stack GS_2 and the fourth gate stack GS_4. The gate insulating layer 132 may be omitted from the first gate stack GS_1 and the third gate stack GS_3.

In some embodiments, the first gate electrode 134A, the second gate electrode 134B, the third gate electrode 134C, and the gate capping layer 136 may be sequentially formed on the substrate 110. The first gate electrode 134A, the second gate electrode 134B, the third gate electrode 134C, and the gate capping layer 136 may be patterned to form the gate stack GS in the peripheral circuit area PCA and form the bit line BL in the cell array area MCA. In some embodiments, the bit line BL may be formed in the cell array area MCA, and the gate stack GS may be formed in the peripheral circuit area PCA.

An inner spacer layer 142L that conformally covers the gate stack GS may be formed. The inner spacer layer 142L may be formed using a first insulating material, and the first insulating material may include silicon nitride.

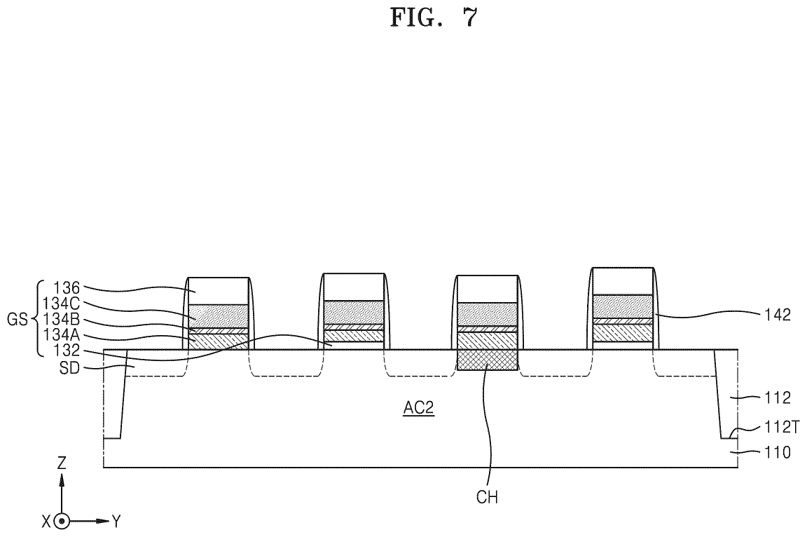

Referring to FIG. 7, an anisotropic etching process may be performed on the inner spacer layer 142L to form an inner spacer 142 on sidewalls of the gate stack GS. An upper surface portion of the second active area AC2 not covered by the gate stack GS and the inner spacer 142 may be re-exposed by the anisotropic etching process.

In some embodiments, after forming the inner spacer 142, an ion implantation process may be used to implant impurities into the second active area AC2 to form the source/drain area SD. In some embodiments, the source/drain area SD may be formed by implanting impurities into the second active area AC2 by an ion implantation process before forming the inner spacer 142.

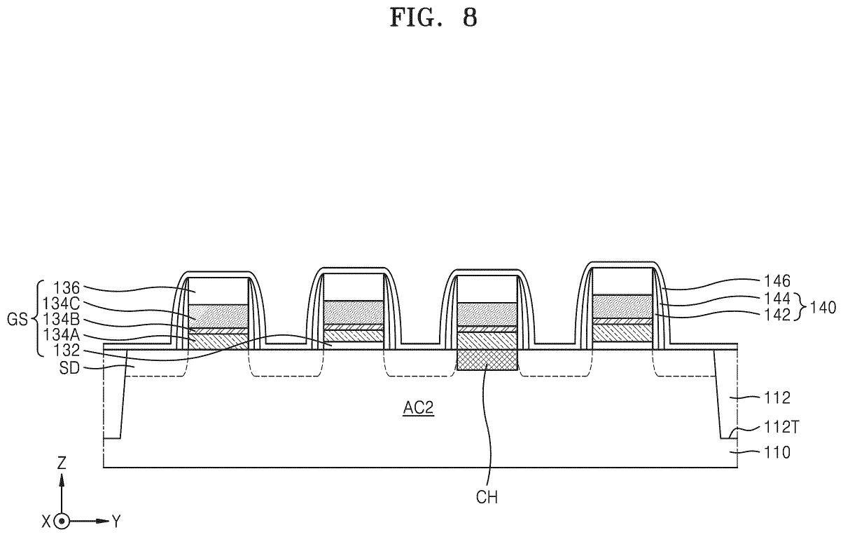

Referring to FIG. 8, an outer spacer layer (not shown) covering the gate stack GS and the inner spacer 142 may be formed on the substrate 110, and an anisotropic etching process may be performed on the outer spacer layer to form the outer spacer 144 on both sidewalls of the gate stack GS. The outer spacer 144 may include a second insulating material, and the second insulating material may include, but is not necessarily limited to, silicon oxide. A bottom surface of the outer spacer 144 may be disposed on the upper surface of the source/drain area SD.

The protective layer 146 that conformally covers the gate stack GS, the inner spacer 142, and the outer spacer 144 may be formed. The protective layer 146 may cover the upper surface of the source/drain area SD.

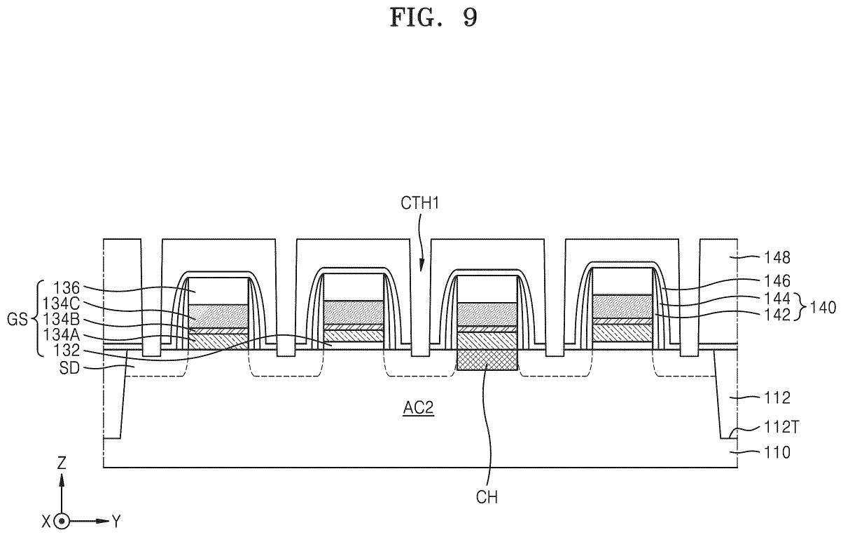

Referring to FIG. 9, the first interlayer insulating film 148 may be formed on the protective layer 146. The first interlayer insulating film 148 may be formed to a height sufficient to completely cover the gate stack GS. The height of the first interlayer insulating film 148 may be based on a height of a tallest gate stack. In a case that a height of a thin PMOS stack may be reduced to be equal to or less than a height of another gate stack, the height of the first interlayer insulating film 148 may be reduced.

Subsequently, a mask pattern (not shown) may be formed on the first interlayer insulating film 148, and the mask pattern may be used as an etching mask to remove a portion of the first interlayer insulating film 148 and the protective layer 146 to form the contact hole CTH1. The upper surface of the source/drain area SD may be exposed at a bottom portion of the contact hole CTH1.

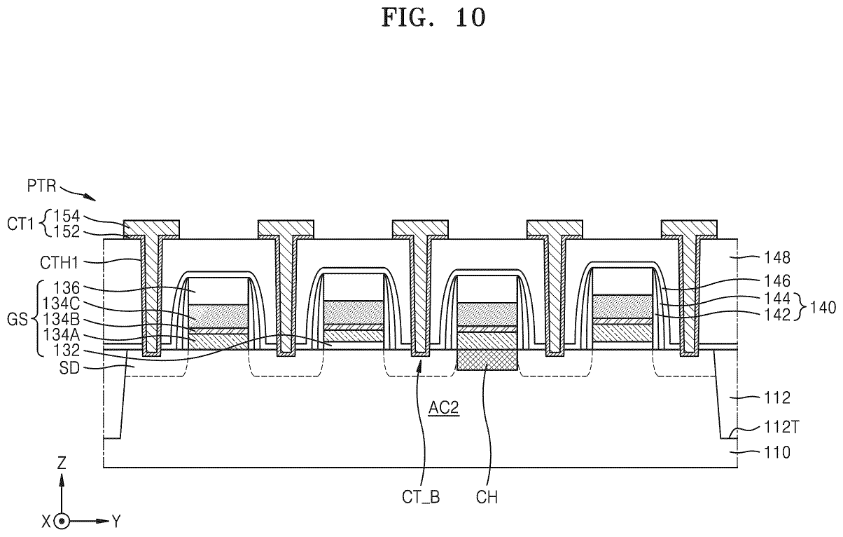

Referring to FIG. 10, the contact CT1 including the conductive barrier 152 and the contact conductive layer 154 may be formed on an inner wall of the contact hole CTH1.

In some embodiments, the conductive barrier 152 may include at least one of ruthenium (Ru), titanium (Ti), titanium nitride (TiN), tantalum (Ta), tantalum nitride (TaN), tungsten (W), titanium silicon nitride (TiSiN), titanium silicide (TiSi), or tungsten silicide (WSi). The contact conductive layer 154 may include at least one of tungsten (W), cobalt (Co), molybdenum (Mo), nickel (Ni), ruthenium (Ru), copper (Cu), or aluminum (Al), a silicide thereof, or an alloy thereof.

Referring again to FIG. 5, the second interlayer insulating film 160 may be formed on the first interlayer insulating film 148 and the contact CT1, and the upper contact 162 may be formed, which may penetrate the second interlayer insulating film 160 and may be electrically connected to the contact CT1.

The integrated circuit device 100 may be completed by performing methods described herein.

FIG. 11 is an enlarged view showing a form of an active area of an integrated circuit device before and after a process, according to an embodiment.

Heated hydrogen may facilitate the migration of silicon. Referring to FIG. 11, hydrogen annealing may be used to promote silicon migration and form etched silicon-on-insulator (SOI) islands having different structures, such as microspheres and rounded beams.

FIG. 11 is referred to in conjunction with FIG. 5. FIG. 11 illustrates deformation of the active area AC during a process. After a process of the active area AC is completed, an epitaxial growth process may be performed to place the channel semiconductor layer CH on the active area AC. Illustration (a) of FIG. 11 illustrates an active area AC of a thin PMOS. That is, an active area AC illustrated in FIG. 11 may correspond to an active area AC positioned beneath the third gate stack GS_3 of FIG. 5. A process of generating the active area AC of FIG. 11 may have different input process values compared to processes performed on other active areas, and may be performed independently in terms of time or process.

A bake process may be performed on the active area AC. When a general bake process is performed, hydrogen atoms of a hydrogen gas may be implanted. Another material may not be implanted. During a bake process, annealed silicon atoms in the active area AC may have their crystal lattice structure broken. The silicon atoms with a broken crystal lattice structure may be subject to a migration to lower their energy. More specifically, the crystal lattice structure of the silicon atoms at the edges of the active area AC may be easily broken. In this case, the migration may proceed toward the center of the active area AC. This phenomenon may be the rounding phenomenon described herein. According to the inventive concept, elements of the bake process may be modified to alleviate or eliminate rounding of an upper portion of the active area AC that may result from the rounding phenomenon. Factors affecting a bake process may include temperature, time, and type of implanted atoms.

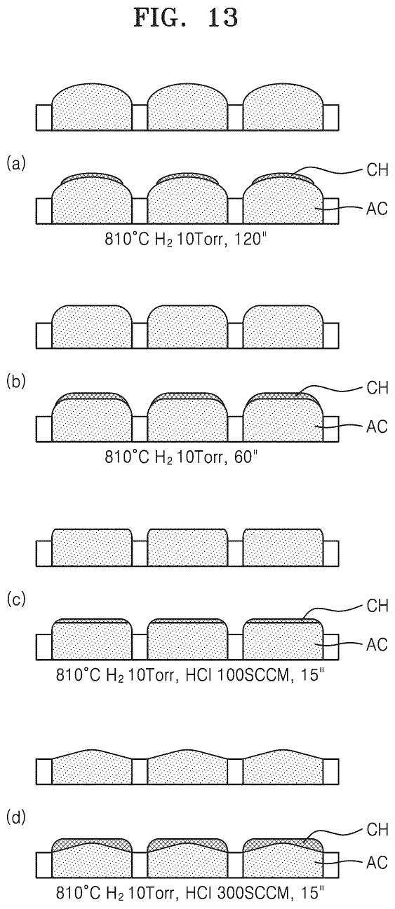

FIG. 12 shows transmission electron microscope images of an active area of an integrated circuit device under different process conditions, according to an embodiment. FIG. 13 shows cross-sectional views of an active area of an integrated circuit device under different process conditions, according to an embodiment.

FIG. 12 and FIG. 13 will be referred to together. A process may be performed at a fixed temperature of about 810 degrees (° C.). A bake process may be performed by lowering the temperature of the bake process. Lowering the bake temperature may suppress the rounding phenomenon of the active area AC and alleviate the dent structure by not providing sufficient energy for the silicon atoms to migrate. A bake process, as a process for forming an active area AC having a low upper level, may be performed at a temperature range of about 700 degrees (° C.) to about 900 degrees (° C.). However, FIG. 12 and FIG. 13 show example results of a process conducted at about 810 degrees (° C.).

A time factor of the bake process is adjusted. FIG. 12 and FIG. 13 illustrate examples performed (a) for 120 seconds (″), (b) for 60 seconds, and (c) and (d) for 15 seconds, respectively. By reducing the baking time, sufficient time for silicon atoms to migrate may not be provided, and the rounding phenomenon may be suppressed in the active area AC and the dent structure may be mitigated. A process of generating the active area AC having the low upper level may be performed for a period of about 5 seconds to about 500 seconds.

To reduce the rounding phenomenon of the active area AC and to reduce the height difference of the thin PMOS and the thin NMOS expressed by an epitaxial growth process of cSiGe, which may be the channel semiconductor layer CH, a final height of the thin PMOS may be formed low. That is, if the active area AC on which the channel semiconductor layer CH grows may be etched, the height of the thin PMOS may be reduced. To efficiently perform etching, according to the inventive concept, hydrogen chloride (HCl) atoms and hydrogen (H₂) atoms may be implanted. The hydrogen chloride (HCl) atoms and hydrogen (H₂) atoms may be supplied by a hydrogen chloride (HCl) gas and hydrogen (H₂) gas, respectively.

Interface etching using hydrogen chloride may be performed by a mechanism in which chlorine (Cl) may selectively react with silicon. The chemical reaction for the mechanism may be expressed as [Chemical Formula 1].

Si(s)+2HCl(g)→SiCl₂(g)+H₂(g) [Chemical Formula 1]

Additionally, if carbon (C)-based impurities exist at the silicon interface, a method of etching the impurities simultaneously may be performed. The chemical reaction therefor may be expressed as [Chemical Formula 2].

Si(s)−C+2HCl(g)→SiCl₂(g)+C-H₂(g) [Chemical Formula 2]

Hydrogen chloride atoms supplied by a hydrogen chloride gas may be implanted in a range of about 1 Standard CC per Minute (SCCM) to about 300 SCCM. In the inventive concept, results of implanting 100 SCCM or 300 SCCM are shown by way of example.

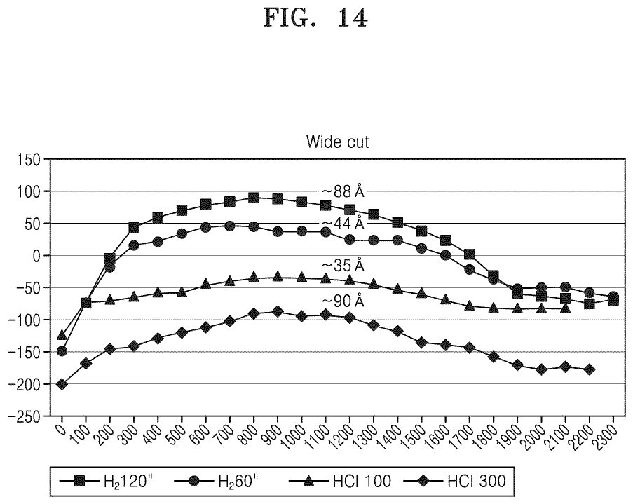

FIG. 14 is a graph comparing progress results of different process conditions of an integrated circuit device according to an embodiment.

Considering the factors in combination, examples (a) to (d) of FIG. 12 and FIG. 13 are described in detail with reference to FIG. 14. In example (a), process conditions may be about 810° C., H₂ at about 10 Torr, and about 120 seconds as a bake process according to a comparative embodiment. In example (b) the bake time may be about 60 seconds. In example (b), the rounding phenomenon of the active area AC may not be significantly alleviated. In example (c), 100 SCCM of hydrogen chloride may be introduced, and the bake time may be about 15 seconds. When a process is performed under appropriate conditions, the active area AC of the silicon may be etched by about 35 Å, the flatness of the active area AC may be improved, and the active area AC may be formed conformally. In addition, in the case of SiGe, which is the channel semiconductor layer CH, the channel semiconductor layer CH may grow conformally while maintaining flatness. In example (d) the implant amount of hydrogen chloride may be increased to about 300 SCCM. As a result, excessive etching may occur, and the active area AC may be etched by about 90 Å, leading to a reduced flatness. In view of examples (a) to (d), a condition for the implant amount of hydrogen chloride may be about 100 SCCM, which may effectively inhibit the rounding phenomenon. However, the conditions may be varied depending on the type of active area AC and the dimensions of the active area AC.

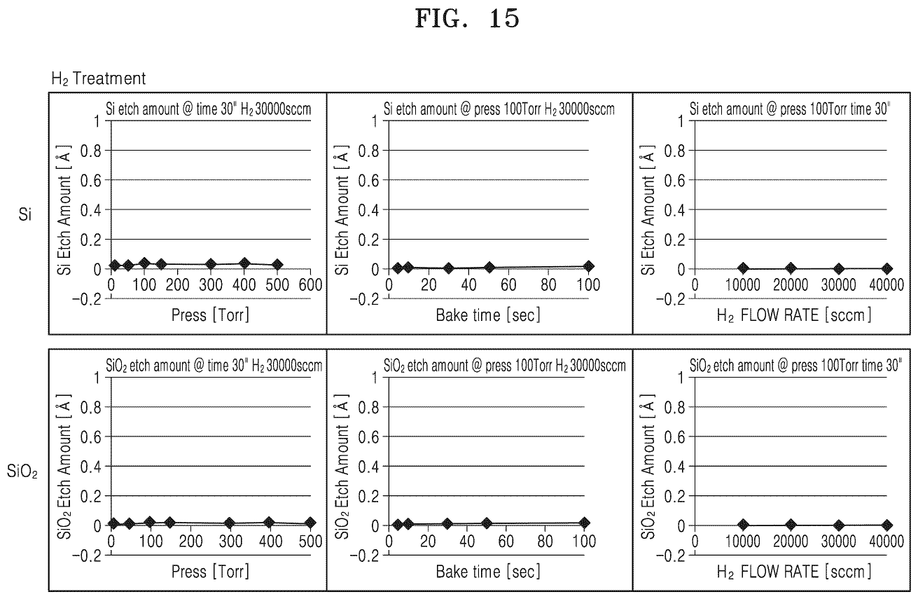

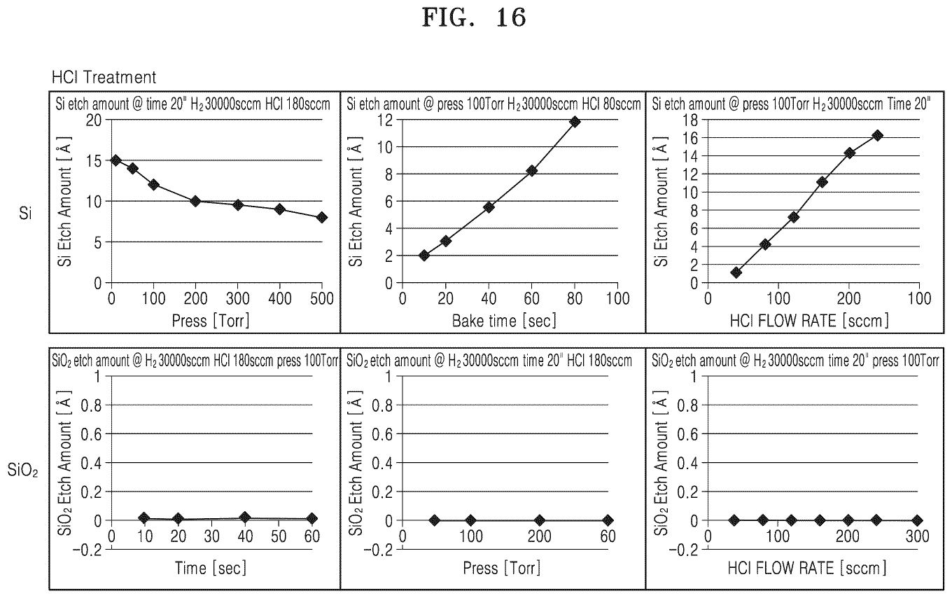

FIG. 15 is a graph comparing the etching amount by an etching process for an integrated circuit device according to an embodiment. FIG. 16 is a graph comparing the etching amount by another etching process for an integrated circuit device according to an embodiment.

Referring to FIG. 15, it may be confirmed that in the case of process treatment using only hydrogen gas, there may be no etching effect on silicon and silicon oxide (SiO₂) films by hydrogen. It may also be confirmed that the results are the same regardless of changes in hydrogen gas flow rate, bake time, or pressure. An embodiment of FIG. 16 is described. On the other hand, in the case of process treatment using hydrogen chloride gas, it may be seen that the etching amount for silicon increases in proportion to the increase in flow rate and time. Additionally, in terms of pressure, it may be confirmed that the etching amount may be greatest at 100 Torr or less. Regarding the silicon oxide film, as in a process treatment using only hydrogen gas, the amount of etching may be independent of the flow rate, pressure, and time increase. This indicates that the higher the density of silicon atoms located at the interface, the more silicon dangling bonds may be exposed to the outside, and the reaction of the etching process may be activated. Here, hydrogen chloride may be used as an etchant that may selectively etch silicon compared to silicon oxide.

When using hydrogen chloride, the removal speed of silicon may be faster than when using only hydrogen gas, and the removal of impurities may also proceed smoothly. Additionally, in the case that hydrogen chloride may be generated during the epitaxial growth process that forms the channel semiconductor layer CH, a risk of contamination by chlorine may be avoided.

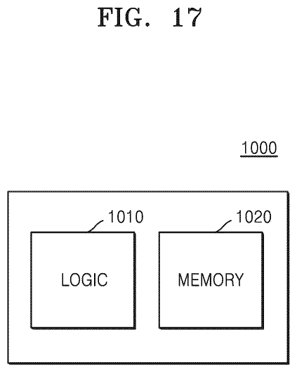

FIG. 17 is a block diagram of an electronic device according to some embodiments.

Referring to FIG. 17, an electronic device 1000 includes a logic area 1010 and a memory area 1020.

The logic area 1010 may include, as standard cells that may perform logical functions. The logical functions may include counters and buffers, various types of logic cells including a plurality of circuit elements including transistors, or registers. Examples of the logic cells may include AND, NAND, OR, NOR, XOR (exclusive OR), XNOR (exclusive NOR), INV (inverter), ADD (adder), BUF (buffer), DLY (delay), FILL (filter), multiplexers (MXT/MXIT), OAI (OR/AND/INVERTER), AO (AND/OR), AOI (AND/OR/INVERTER), D flip-flops, reset flip-flops, master-slaver flip-flops, or latches. However, the logic cells listed are merely examples, and the logic cells according to the inventive concept are not necessarily limited to the cells exemplified herein.

The memory area 1020 may include at least one of static random-access memory (SRAM), DRAM, magnetic random-access memory (MRAM), resistive random-access memory (RRAM), and phase change random-access memory (PRAM).

The logic area 1010 and the memory area 1020 may include at least one of the integrated circuit devices 100 described with reference to FIGS. 1A-1B, 2A-2B, and 3 to 10 and integrated circuit elements having various structures modified and changed therefrom within the scope of the inventive concept.

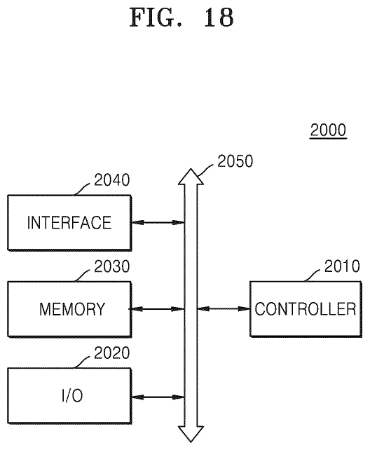

FIG. 18 is a block diagram of an electronic system according to some embodiments.

Referring to FIG. 18, an electronic system 2000 includes a controller 2010, an input/output device (I/O) 2020, a memory 2030, and an interface 2040, which are each interconnected via a bus 2050.

The controller 2010 may include at least one of a microprocessor, a digital signal processor, or a similar processing device. The input/output device 2020 may include at least one of a keypad, a keyboard, or a display. The memory 2030 may be used to store commands executed by the controller 2010. For example, the memory 2030 may be used to store user data.

The electronic system 2000 may include a wireless communication device, or a device capable of transmitting and/or receiving information in a wireless environment. In order to transmit/receive data through a wireless communication network in the electronic system 2000, the interface 2040 may include a wireless interface. The interface 2040 may include an antenna and/or a wireless transceiver. In some embodiments, the electronic system 2000 may be used for communication interface protocols of a third-generation communication system, including code division multiple access (CDMA), global system for mobile communications (GSM), north American digital cellular (NADC), extended-time division multiple access (E-TDMA), and/or wide band code division multiple access (WCDMA). The electronic system 2000 may include at least one of the integrated circuit devices 100 described with reference to FIGS. 1A-1B, 2A-2B, and 3 to 10 and integrated circuit elements having various structures modified and changed therefrom within the scope of the inventive concept.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a plurality of gate stacks disposed on a substrate and comprising a first gate stack and a second gate stack;
a spacer disposed on sidewalls of each of the plurality of gate stacks;
a plurality of source/drain areas disposed in an upper portion of the substrate and at sides of the plurality of gate stacks;
an active area disposed in the upper portion of the substrate and between adjacent source/drain areas of the plurality of source/drain areas; and
a channel semiconductor layer disposed between the active area and the second gate stack among the plurality of gate stacks,
wherein an upper level of a first portion of the active area disposed at a lower portion of the first gate stack is higher than an upper level of a second portion of the active area disposed at a lower portion of the second gate stack.

2. The integrated circuit device of claim 1,
wherein the channel semiconductor layer is formed conformally on an upper surface of the second portion of the active area, and
an upper level of the channel semiconductor layer is coplanar with the upper level of the first portion of the active area.

3. The integrated circuit device of claim 1,
wherein the channel semiconductor layer comprises silicon germanium (SiGe), and the plurality of source/drain areas comprise silicon doped with impurities.

4. The integrated circuit device of claim 1,
wherein the second portion of the active area has an upper surface with a conformal level.

5. The integrated circuit device of claim 1, wherein the first gate stack is an n-channel metal-oxide semiconductor and the second gate stack is a p-channel metal-oxide semiconductor, and the first gate stack and the second gate stack are disposed adjacent to each other.

6. The integrated circuit device of claim 5, wherein the plurality of gate stacks further comprise:
a third gate stack disposed adjacent to the first gate stack and spaced apart from the second gate stack; and
a fourth gate stack disposed adjacent to the second gate stack and spaced apart from the first gate stack,
wherein the third gate stack is an n-channel metal-oxide semiconductor and the fourth gate stack is a p-channel metal-oxide semiconductor,
wherein an upper level of a third portion of the active area disposed at a lower portion of the third gate stack and an upper level of a fourth portion of the active area disposed at a lower portion of the fourth gate stack have a level of the upper level of the first portion of the active area.

7. The integrated circuit device of claim 6,
wherein each of the plurality of gate stacks comprises a first gate electrode, a second gate electrode, and a third gate electrode,
the first gate electrode, the second gate electrode, and the third gate electrode are sequentially arranged from a lower surface of the gate stack toward an upper surface of the gate stack,
a thicknesses of each of the first gate electrode to the third gate electrode in a vertical direction are different from one another, and
a height of the fourth gate stack is highest among the plurality of gate stacks.

8. The integrated circuit device of claim 7, wherein the third gate stack is disposed directly on the active area, and
wherein each of the first gate stack and the fourth gate stack comprises a gate insulating layer disposed between the first gate electrode and the active area.

9. The integrated circuit device of claim 1,
wherein each of the plurality of gate stacks comprises a first gate electrode, a second gate electrode, and a third gate electrode,
the first gate electrode, the second gate electrode, and the third gate electrode are sequentially arranged from a lower surface of the gate stack toward an upper surface of the gate stack,
a thicknesses of each of the first gate electrode to the third gate electrode in a vertical direction are different from one another,
the first gate electrode comprises Si, Ge, W, WN, Co, Ni, Al, Mo, Ru, Ti, TiN, Ta, TaN, Cu, or La, or a combination thereof, and
the second gate electrode and the third gate electrode each comprise TiN, TiSiN, W, or tungsten silicide, or a combination thereof.

10. The integrated circuit device of claim 9, wherein the plurality of gate stacks further comprise:
a third gate stack disposed adjacent to the first gate stack and spaced apart from the second gate stack; and
a fourth gate stack disposed adjacent to the second gate stack and spaced apart from the first gate stack,
wherein each of the first gate stack and the third gate stack forms a n-channel metal-oxide semiconductor (NMOS),
wherein each of the second gate stack and the fourth gate stack forms a p-channel metal-oxide semiconductor (PMOS), and
wherein each of the first gate stack and the fourth gate stack comprises a gate insulating layer disposed beneath the first gate electrode.

11. An integrated circuit device comprising:
a plurality of gate stacks disposed on a substrate and comprising a gate electrode and a gate capping layer, the plurality of gate stacks comprising a first gate stack, a second gate stack, a third gate stack, and a fourth gate stack;
a spacer disposed on sidewalls of each of the plurality of gate stacks, the spacer including an inner spacer disposed on the sidewalls of each the plurality of gate stacks and an outer spacer disposed on the inner spacer on the sidewalls of each the plurality of gate stacks;
a plurality of source/drain areas disposed at sides of each of the plurality of gate stacks in an upper portion of the substrate;
an active area disposed in the upper portion of the substrate and between the plurality of source/drain areas;
a channel semiconductor layer disposed between the active area and the third gate stack among the plurality of gate stacks;
a protective layer covering each of the spacer and the plurality of gate stacks; and
an interlayer insulating film disposed on an upper surface of the protective layer,
wherein the active area is configured such that an upper level of the active areas varies,
wherein the upper level of a portion of the active area disposed at a lower portion of the third gate stack is lower than the upper level of another portion of the active area, and
wherein the channel semiconductor layer is conformally formed on an upper surface of the active area.

12. The integrated circuit device of claim 11, wherein the channel semiconductor layer comprises silicon germanium (SiGe), and has a thickness equal to a difference in a vertical level between the upper level of the portion of the active area and the upper level of the another portion of the active area.

13. The integrated circuit device of claim 11, wherein the portion of the active area disposed at the lower portion of the third gate stack has an upper surface with a conformal level.

14. The integrated circuit device of claim 11,
wherein each of the first gate stack and the second gate stack forms an n-channel metal-oxide semiconductor (NMOS),
wherein each of the third gate stack and the fourth gate stack forms a p-channel metal-oxide semiconductor (PMOS),
wherein the gate electrode comprises a first gate electrode to a third gate electrode,
wherein each of the second gate stack and the fourth gate stack comprises a gate insulating layer,
wherein the first gate electrode, the second electrode, and third gate electrodes are sequentially arranged from a lower surface to the upper surface of the gate stack, and
wherein the gate insulating layer is disposed beneath the first gate electrode.

15. The integrated circuit device of claim 14,
wherein an uppermost level of each of the first gate stack to the fourth gate stack is different from each other,
wherein the uppermost level of the third gate stack is lower than or equal to the uppermost level of the fourth gate stack, and
wherein the uppermost level of the first gate stack is lower than or equal to the uppermost levels of the second gate stack, the third gate stack, and the fourth gate stack.

16. The integrated circuit device of claim 11,
further comprising a contact disposed penetrating through the interlayer insulating film and the protective layer, the contact having a bottom portion in contact with a source/drain area of the plurality of source/drain areas.

17. The integrated circuit device of claim 16,
wherein a bottom surface of the contact is disposed at a level lower than the upper surface of the source/drain area.

18. An integrated circuit device comprising:
an element isolation film disposed on a substrate and defining an active area;
a plurality of gate stacks disposed on the active area of the substrate and comprising a gate electrode and a gate capping layer, the plurality of gate stacks comprising a first gate stack, a second gate stack, a third gate stack, and a fourth gate stack;
a spacer disposed on sidewalls of each of the plurality of gate stacks and comprising an inner spacer and an outer spacer;
a plurality of source/drain areas disposed at sides of the plurality of gate stacks and in an upper portion of the substrate; and
a channel semiconductor layer disposed between the active area and the third gate stack among the plurality of gate stacks,
wherein an upper level of a portion of the active area disposed at a lower portion of the third gate stack is lower than the upper levels of portions of the active area disposed at lower portions of the first gate stack, the second gate stack, and the fourth gate stack,
wherein the channel semiconductor layer is conformally formed on an upper surface of the active area at the lower portion of the third gate stack,
wherein the active area at the lower portion of the third gate stack has an upper surface with a conformal level,
wherein uppermost levels of the first gate stack to the fourth gate stack are different from each other,
wherein the uppermost level of the third gate stack is lower than or equal to the uppermost level of the fourth gate stack,
wherein the uppermost level of the first gate stack is lower than or equal to the uppermost levels of the second gate stack, the third gate stack, and the fourth gate stack,
wherein the first gate stack is disposed directly on the active area, and
wherein each of the second gate stack and the fourth gate stack comprises a gate insulating layer disposed on the active area.

19. The integrated circuit device of claim 18, wherein a process for forming the active area at the lower portion of the third gate stack is performed at a temperature range of about 700 degrees (° C.) to about 900 degrees (° C.), and for a period of about 5 seconds to about 500 seconds.

20. The integrated circuit device of claim 18, wherein a process for forming the active area at the lower portion of the third gate stack comprises implanting hydrogen from a hydrogen gas and hydrogen chloride from a hydrogen chloride gas,
wherein the hydrogen chloride is implanted in a range from about 1 Standard CC per Minute (SCCM) to about 300 SCCM.
